(19) United States
(12) Patent Application Publication
(10) Pub. No.: US 2005/0106508 A1
(43) Pub. Date: May 19, 2005

(54) Method of fabricating devices and observing the same

(76) Inventors: Toshimichi Shintani, Kodaira (JP); Yumiko Anzai, Ome (JP); Hiroyuki Minemura, Kokubunji (JP); Harukazu Miyamoto, Higashimurayama (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/933,215

(22) Filed: Sep. 3, 2004

(30) Foreign Application Priority Data
Sep. 25, 2003 (JP) 2003-332657

(51) Int. Cl. G03F 7/00

(52) U.S. Cl. 430/322; 430/329

(57) ABSTRACT

In fabricating process using a light beam or electron beam, reactivity is determined by the total amounts of photons or electrons absorbed by resist and consequently, fine fabrication cannot be achieved. On the other hand, thermal recording has been proposed but in the thermal recording, miniaturization of the fabrication size depends on a spot size of light beam or electron beam used for recording and is limited. Under the circumstance, to ensure a fine uneven pattern to be produced with high reproducibility, only crystal of a recording film used in a phase-change optical disk is peeled off by using an alkaline solution or pure water to leave only an amorphous portion on the sample surface and as a result, crystalline and amorphous patterns are converted into an uneven pattern.

### INCORPORATION BY REFERENCE

The present application claims priority from Japanese application JP2003-332657 filed on Sep. 25, 2003, the content of which is hereby incorporated by reference into this application.

### BACKGROUND OF THE INVENTION

The present invention relates to a method for micro-pattern fabrication and a method of observing an arrangement of atoms and molecules in a sample.

In the process to fabricate a semiconductor, resist, having its reactivity changeable under irradiation of a laser beam or electron beam (EB), is coated on a substrate and after being irradiated with the laser beam or EB, the coated resist is developed so that an irradiated portion or unirradiated portion may be removed to produce an uneven pattern. In this case, a focusing optical system is used for the laser beam or EB and when taking the laser beam, for instance, a focused spot diameter can be written by λ/NA where λ represents the wavelength and NA represents the numerical aperture. Accordingly, a fine pattern has been formed by making λ small and NA large to reduce the spot diameter. Today, the development of a technique using an ArF laser has been in progress. The ArF laser has a wavelength of 193 nm and with this type of light source, fabrication of a line width of about 100 nm is achieved at present and the study and development of fabrication of finer line widths has been in progress. With the EB, the wavelength can be shortened depending on accelerating voltage and at present, fabrication of a line of about 30 nm width achieved in the case of an isolated pattern.

The reactivity of the resist used for fabrication as above is determined by the total irradiation amounts of a beam such as laser beam or EB. For example, in exposure using a laser beam, a reaction takes place at a portion where the total of numbers of photons absorbed by resist molecules exceeds a threshold value, so that the portion can have its solubility in a developer, which solubility differs from that of another portion where the threshold value is not exceeded, and an uneven pattern can be formed by means of the developer. In EB drawing, increased sensitivity to the EB causes acid generated in the resist under the irradiation of the EB to diffuse, with the result that solubility in the developer is changed by the acid. But the reactivity is determined by the total irradiation amounts of the electron beam as in the case of the laser beam.

Further, in the field of optical disk, for example, read-only (ROM) disk, write once read many disk and rewritable disk are on the market. Taking a DVD, for instance, a ROM disk is called a DVD-ROM and a write once read many disk is called a DVD-R. In the rewritable disk, phase-change recording to be described later is used and DVD-RAM, DVD−RW and DVD+RW are involved.

A substrate of each of the aforementioned ROM disk, write once read many disk and rewritable disk is formed with a pattern of pits corresponding to data and track grooves. The pits and grooves are generally formed through a process having the following steps of 1. coating photosensitive resist on a glass substrate, 2. rotating the substrate and irradiating a laser beam focused by an objective lens onto the substrate so as to cause the resist to undergo light exposure, 3. developing the substrate to provide an uneven pattern based on an exposed pattern and 4. plating the resulting uneven pattern with metal such as Ni to form an original, pouring molten polycarbonate to the original and solidifying the molten polycarbonate to form a substrate. The light exposure based on the laser beam is called cutting and a unit for this purpose is called a cutting unit. A series of process steps of fabricating the original is called mastering.

In case grooves are formed in the step 2 as above, a DC beam is used as the incident laser beam and in the case of formation of pits, a pulsed beam meeting a suitable condition is used. The condition is optimized in consideration of the sensitivity of resist or the like.

For fabrication of a high-density optical disk, it is necessary that a small pit or a narrow track groove be formed with high accuracies. To this end, the spot size of an incident light beam needs to be minimized. The beam is focused to an optical spot having a diameter proportional to λ/NA, where λ represents the wavelength and NA represents the numerical aperture of an objective lens. According to presently proposed specifications of next generation optical disks, a 120 mm-diameter disk having the shortest mark length amounting to 0.15 to 0.2 μm and a track pitch of about 0.3 to 0.35 μm has a capacity of 20 to 30 GB. In order to form a pit commensurate with this size, the cutting unit has a wavelength of 250 to 270 nm and the NA is about 0.9.

The resist used for cutting in an optical disk also has properties similar to those of the resist used for fabrication of a semiconductor and its reactivity is determined by the total irradiation amounts of a beam.

In the case of the phase-change record used for rewritable disks, a focused, highly intensive laser beam is irradiated on a medium when a mark is recorded, with the result that a recoding film absorbs the beam to generate heat by which the recording film is molten locally. When the temperature at a molten portion is lowered abruptly, the portion becomes amorphous. The melting point differs with the composition of a material but typically, it approximately amounts to 550° C. to 700° C. Typically, the phase-change recording film has a crystallizing temperature region corresponding to a temperature range between 200° C. and the melting point or less. When a portion of the recording film is applied with heat, it is determined, by a time for which the portion stays in the crystallizing temperature region, whether that portion thereafter becomes crystalline or amorphous. More specifically, the aforementioned portion becomes amorphous when the time of staying in the crystallizing temperature region is shorter than a certain time but becomes crystalline when longer. Therefore, the phase-change record is used for rewritable optical disks. To describe more specifically, a laser beam of high power is irradiated onto a portion where a mark is to be recorded so that the portion may be heated to high temperatures. Thereafter, when the laser beam irradiation is turned off, the portion is molten and its temperature subsequently decreases abruptly, with the result that the time of staying in the crystallizing temperature region is short and the portion becomes amorphous. For crystallization, on the other hand, a portion is irradiated with a laser beam of relatively low power so as to be heated to the crystallizing temperature region and is kept at a relatively low temperature, so that the portion can stay in the crystallizing temperature region for a longer time than that in the above case and can be crystallized. In this manner, both the mark recording and the mark erasing can be achieved to materialize a rewritable optical disk.

Reproduction of a recorded signal utilizes the difference in reflectivity attributable to the difference in refractive index between amorphous and crystal and is carried out by detecting an amount of reflected beam of an incident beam for reproduction.

As described above, crystal or amorphous is determined depending on whether the time of staying in the crystallizing temperature region is long or short and the temporal boundary differs for materials of the phase-change recording film. For example, a recording film widely used for a DVD−RW is crystallized in a relatively short time but a recording film used for a DVD-RAM requires a relatively long time for crystallization. Generally, the former is called a recording film of high crystallization rate and the latter is called a recording film of low crystallization rate. Proceeding of SPIE Vol. 4342, “Optical Data Storage 2001”, pp. 76 to 87, (2002) (Non-Patent Document 1) reports that the crystallization rate can be controlled by the content of Sb.

In order to obtain a reproduction signal of high quality in a phase-change optical disk, diffusion of heat generated in a recording film during recording and crystallization characteristics of the recording film must be controlled. Accordingly, in the study and development of phase-change optical disks, the shape of a recorded mark sometimes needs to be observed. For the observation, a transmission electron microscope (TEM) has hitherto been used principally and an electron beam diffraction figure due to a crystal lattice is utilized to discriminate a crystalline region from an amorphous region. Apart from the TEM, a method in which a scanning electron microscope (SEM) is used and observation is carried out on the basis of the difference in generation of secondary electrons between a crystalline portion and an amorphous portion and another method in which a surface potential microscope, a kind of probe microscope, is used and the shape of a mark is observed from the difference in surface potential between a crystalline portion and an amorphous portion are reported in Ricoh Technical Report No. 7, pp. 8-14 (2001) (Non-Patent Document 2) and Proceedings of the 14^{th} Symposium on Phase-change Optical Information Storage, pp. 52-55 (2002) (Non-Patent Document 3), respectively.

### SUMMARY OF THE INVENTION

The conventional fabrication method for semiconductors and optical disk substrates is carried out with a system in which the reactivity of resist is proportional to the total irradiation amounts of a beam and in such a system, fineness of fabrication is limited. For example, an instance is considered in which while a laser beam is scanned, a fine line and space (L&S) pattern is drawn line by line. Then, a gaussian beam 201 having a threshold value 202 as shown in FIG. 2A is irradiated on resist and a region 203 reacts. Subsequently, a gaussian beam 204 of the same power is scanned to expose adjacencies as shown in FIG. 2B. In this case, a region 205 reacts but power of a skirt of the gaussian beam 204 is irradiated in the vicinity of the region 203 to create a portion in which the total number of absorbed photons exceeds a reaction threshold value and as a result, a region 206 reacts newly. The beam 201 identically affects the region 205 and a region 207 reacts newly.

This holds true also for the EB drawing.

Conceivably, for avoidance of the inconvenience as above, the amount of irradiation of a beam is calculated in advance with a view to correcting power of the beam. In this method, however, power must sometimes be lowered drastically in order that a pattern of very high density can be produced. Accordingly, only partial power near the peak of gaussian beam distribution is used and in such an event, as the power of the beam varies, the pattern changes to a great extent. In other words, power margin of the beam is degraded. This leads to degraded reproducibility of fabrication to remarkably reduce the yield of patterns and devices to be fabricated.

To solve this problem, a ROM disk fabrication method based on heat has been proposed in the field of optical disk. In this method, a laser beam is irradiated on a medium and the medium is partly changed by heat generated owing to absorption of light by the medium so as to perform recording. In the thermal recording, too, only a portion at which the temperature exceeds a threshold value reacts, as in the case of FIG. 2A, to form a pattern. But heat once generated diffuses and thereafter, the influence of the beam 201 can be cancelled after passage of the beam when drawing as shown in FIG. 2B, for example, is made. Accordingly, if the beam 204 is scanned after the medium has been cooled sufficiently following the passage of the beam 201, then interference with heat can be excluded and the influence of the former beam can be handled substantially independently of that of the latter beam. Namely, reactions at the regions 206 and 207 in FIG. 2B can be suppressed. An example based on this principle and succeeding in improvements in recording data density of cutting in an optical disk is reported in Japanese Journal of Applied Physics, Vol. 42, pp. 769 to 771 (2003) (Non-Patent Document 4).

Even with the aforementioned thermal recording, however, there is a limitation on fine fabrication. The size of an object to be fabricated thermally is determined by a threshold value of temperature and therefore, in fabricating a fine pattern, the power needs to be reduced. Then, power of only a part near the peak of beam distribution is used and power margin is degraded as described previously.

As for the technique of observing the phase-change medium, the TEM has the highest resolution. With the TEM, however, only a recording film of a medium must be taken out of or extracted from the medium but this operation is very difficult to achieve depending on the structure of medium. In addition, even if the recording film can be obtained, a desired portion inside the medium cannot be taken out, thus making it difficult to prepare a specimen observable by the TEM. Several months are often consumed for specimen preparation. Further, the TEM is special equipment and the cost of observation is high.

The method of detecting the difference in generation of secondary electrons between crystal and amorphous by using the SEM succeeds in observation of, for example, AgInSbTe representing a phase-change recording film material often used for DVD−RW or the like but this method is not effective for observation of GeSbTe representing one of other typical phase-change recording film materials. The detailed reason for this is unknown but conceivably, the following will account for the cause: in the case of AgInSbTe, its crystal is semimetal and its amorphous is semiconductor whereas in the case of GeSbTe, its crystal and amorphous are both semiconductors. As will be seen from the above, this method lacks general applicability.

The method using the surface potential microscope has achieved observation of marks. But this method is insufficient to discuss the characteristics of the medium and the improvement of the recording method from the shapes of the observed marks because of its lower resolution than that of TEM or SEM.

An object of the present invention is facilitate fabrication and observation by changing patterns of crystal and amorphous to an uneven pattern through the use of the difference in chemical properties between the crystal and the amorphous.

Solubility of GeSbTe and AgInSbTe, representing materials of typical phase-change recording films, in an alkaline solution is lower when the film is amorphous than when the film is crystalline. By making use of this nature, of crystalline and amorphous patterns, only crystalline one is rendered to be dissolved while leaving amorphous unresolved, thereby ensuring that the crystal and amorphous patterns can be converted into an uneven pattern.

The difference in solubility differs for materials of a layer underlying a phase-change recording film. A sample having a structure of glass substrate, underlying layer and Ge₅Sb₇₀Te₂₅ crystalline film (30 nm) is dipped in a NaOH solution to measure time tcdis necessary for the crystal to dissolve in relation to a variable of concentration of the NaOH solution and measurement results as depicted in FIG. 3 are obtained. Used as the underlying layer are SiO₂ and Cr₂O₃ layers and a (ZnS)₈₀(SiO₂)₂₀ layer representing a protective film widely used in the phase-change recording medium. Within the depicted time, the amorphous portion is not at all dissolved. In the case of the underlying layer being of SiO₂, it is confirmed that when the sample is dipped in pure water, the crystalline portion peels off from the interface to leave only the amorphous on the sample surface. Further, with a NaOH solution having higher concentration than that shown in FIG. 3, the amorphous is also dissolved. It is confirmed that this stands true for Ge₂Sb₂Te₅ and Ge₅Sb₂Te₈ having different composition ratios of GeSbTe and for AgInSbTe.

The above mechanism will be presumed as below. Regardless of crystal or amorphous, GeSbTe and AgInSbTe exhibit solubility in the alkaline solution. But, in the case of the crystal placed in polycrystalline condition, when the sample is dipped in the solution, crystal grains are freed from the crystal grain boundary which is hydrophilic. The freed crystal grain has a large contact area with the solution and is dissolved within a reduced period of time. The amorphous, on the other hand, has no grain boundary and is hardly freed, thus exhibiting a long time for dissolution. In the case of the underlying layer being of SiO₂, both the grain boundary and SiO₂ are hydrophilic and therefore water permeates into the interface between the two, causing the film to peel off.

In the foregoing, selective removal of the crystalline pattern has been explained but conversely, the amorphous pattern can be removed selectively. For selective removal of the amorphous pattern, dry etching or RIE is applied to the whole of film so that the amorphous can be removed selectively by utilizing the difference in etching rate between the amorphous and crystal, that is, the higher etching rate of the amorphous.

To apply heat to the phase-change recording film, a method of using a laser beam as in the case of the phase-change optical recording is employed and in addition, a method may be employed in which current is conducted through a recording film to generate Joule's heat locally. The method using electric current is realized not only with EB but also by conducting electric current in the phase-change recording film deposited on the substrate with electrode patterns fabricated by some manner.

One advantage of using the phase-change recording film resides in that margin for fine fabrication is high. In recording a mark, changes in recording power from an optimum value and changes in recorded mark length are calculated by changing the crystallization rate of the recording film to obtain results as shown in FIG. 4A. A medium structure used for the calculation is of polycarbonate substrate, protective film, phase-change recording film, protective film, reflection film and polycarbonate substrate and is a typical structure of phase-change optical disks. The calculation is conducted by way of an instance where the initial state of the recording film is crystalline and part of the recording film is molten to record an amorphous mark. A light source of a laser beam has a wavelength of 400 nm, an objective lens has a numerical aperture (NA) of 0.85 and the mark length is 150 nm. Depicted in the figure are an instance of the crystallization rate being 0, an instance of the crystallization rate being relatively slow and an instance of the crystallization rate being fast. The instance of the crystallization rate being 0 is identical to an instance of simple thermal recording. It will be seen from the figure that in the case of the crystallization rate being fast, changes in mark length responsive to changes in recording power are minimized and the margin for recording power can be obtained.

This will be accounted for as below. When recording an amorphous mark by melting a recording film having a finite crystallization rate, a central portion of melting region is heated to high temperatures and cooled abruptly so as to form amorphous whereas the peripheral edge of the melting region is not raised to so high a temperature and is therefore cooled gradually so as to be crystallized. This phenomenon is called recrystallization. When the same temperature change is applied to the recording film, the recrystallized region grows more largely if the crystallization rate is fast. In case the recording power becomes higher, for example, in a system in which recrystallization exists, the melting region becomes large and the recrystallization region also becomes large, with the result that changes in both the regions are cancelled out and the size of an ultimately formed mark is almost intact. This tendency develops more remarkably in the case of the crystallization rate being faster.

The recorded mark has shapes as shown in FIGS. 4B, 4C and 4D in correspondence with instances of the crystallization rate being fast, slow and zero, respectively. The shape in FIG. 4D approximates a round circle and the shape in FIG. 4B is oblong vertically of the spot scanning direction. The latter is a mark shape uniquely observed in the recording film in which the crystallization rate is fast. When the crystallization rate is fast, the melting region takes the form of a round circle or an oblong in the track scanning direction but the tail of the mark is recrystallized by laser power prevailing after the mark has been recorded and the shape as shown in FIG. 4B results. This mechanism is detailed in, for example, Japanese Journal of Applied Physics, Vol. 41, pp. 631-635 (2002) (Non-Patent Document 5). By adjusting the laser power prevailing after the mark recording through the use of this phenomenon, the length of a mark to be formed can be controlled.

As will be seen from the above, by utilizing the recrystallization, the margin for fabricating a fine pattern can be assured.

An example of a typical process when the above-described technique is applied to fabrication is illustrated in FIGS. 1A to 1F. As shown in FIG. 1A, lower protective layer 102, phase-change recording film 103 and upper protective layer 104 are formed on a substrate 101. In general, the state of the phase-change recording film 103 is close to an amorphous state. Heat is applied to the film through any process to crystallize the recording film at least partially as shown at 105 in FIG. 1B. Then, the crystal 105 is locally molten to form an amorphous pattern 106 as shown in FIG. 1C. The upper protective layer 104 is removed through any process to expose the recording film in air. Under this condition, the crystalline portion of the recording film is removed by using an alkaline solution as developer to leave only the amorphous pattern on the sample surface. In case the remaining pattern as shown in FIG. 1E does not have a desired depth, the lower protective layer 101 may be etched through, for example, reactive ion etching (RIE) using the remaining amorphous pattern as a mask.

In the above example, the upper protective layer 104 is provided for the purpose of preventing the recording film from being deformed and oxidized in the course of its melting. The lower protective layer is provided in consideration of preparation of a desired depth pattern as above and besides adhesiveness between the substrate and the recording film. If there is nothing to take care of the above, the lower protective layer may be omitted.

In the foregoing, the method of producing the amorphous pattern through melting has been referred to but a crystalline pattern may be produced in an amorphous recording film. If the crystallization process shown in FIG. 1B is applied to part of a location at which a pattern is formed, an amorphous pattern can be formed at a crystallized portion and a crystalline pattern can be formed at an uncrystallized, amorphous portion.

In the case of formation of amorphous patterns in crystal using the above fabrication method, even if the size of the amorphous pattern is larger than the desired one, a smaller pattern can be formed or the size can be corrected by heating the sample formed with the pattern to crystallize part of the amorphous pattern. One of advantages of fabrication using crystal and amorphous pattern is that the formed pattern can be corrected by crystallizing it. For heating of the sample, the whole of the sample may be heated with a baking oven or part of the pattern may be heated through any process such as irradiation of a laser beam.

The present technique can also be applied to observation of marks recorded on a phase-change medium. By recording marks in advance on a phase-change disk, breaking a medium to expose a recording film to the surface and etching this sample through the aforementioned method, the recorded marks can be converted into an uneven pattern. This uneven pattern can be observed easily with a probe microscope such as SEM or atomic force microscope (AFM). Normally, resolution required for observing a mark shape is about several of tens of nanometers and the resolution of this order can be obtained satisfactorily with the SEM. Extraction of only a recording film needed in connection with a specimen observable with the TEM is unnecessary in the SEM, giving rise to advantages that a sample can be prepared easily, observation with a general-purpose apparatus can be possible and time and cost required for observation can be saved to a great extent.

According to the present invention, crystalline and amorphous patterns can be converted into an uneven pattern. In producing an amorphous pattern by melting crystal, a fine pattern can be prepared with high reproducibility by taking advantage of recrystallization occurring at a location distant from a central portion of a melting region. In addition, by using this technique, recorded marks in a phase-change optical disk can be observed cheaply within a short period of time.

Other objects, features and advantages of the invention will become apparent from the following description of the embodiments of the invention taken in conjunction with the accompanying drawings.

### BRIEF DESCRIPTION OF THE DRAWINGS

FIG. 1A is a sectional view showing a sample structure in a typical example of a fabricating process utilizing the invention.

FIG. 1B is a sectional view showing crystallization of a recording film in the fabricating process.

FIG. 1C is a sectional view showing recording of an amorphous pattern in the fabricating process.

FIG. 1D is a sectional view for explaining removal of an upper protective layer.

FIG. 1E is a sectional view for explaining removal of a crystalline portion of the recording film.

FIG. 1F is a sectional view for explaining etching of a lower protective layer by using the amorphous portion of recording film as a mask.

FIG. 2A is a diagram useful in explaining production of an isolated pattern in conventional fabrication using photosensitive resist.

FIG. 2B is a diagram useful in explaining production of a pattern adjacent to the pattern of FIG. 2A in the conventional fabrication.

FIG. 3 is a graph showing the relation between NaOH concentration and time required for dissolution when a crystalline portion of a Ge₅Sb₇₀Te₂₅ phase-change recording film is dissolved with a NaOH solution.

FIG. 4A is a graph showing the relation between recording power and mark length when recording a phase-change mark by laser beam irradiation is simulated and calculated for the crystallization rate being 0 (simple pure thermal recording), slow and fast, respectively.

FIG. 4B is a diagram showing a mark shape when the crystallization rate is fast in the simulation.

FIG. 4C is a diagram showing a mark shape when the crystallization rate is slow in the simulation.

FIG. 4D is a diagram showing a mark shape when the crystallization rate is 0 in the simulation.

FIG. 5A is a sectional diagram showing a sample structure in fabrication of a ROM substrate of an optical disk according to embodiment 1 of the invention.

FIG. 5B is a sectional view for explaining crystallization of a recording film in the ROM substrate fabrication.

FIG. 5C is a sectional view for explaining production of an amorphous pattern in the ROM substrate fabrication.

FIG. 5D is a sectional view for explaining etching of an upper protective layer and a crystalline portion of the recording film in the ROM substrate fabrication.

FIG. 5E is a sectional view for explaining etching of a lower protective layer by using the recording film and amorphous portion as a mark in the ROM substrate fabrication.

FIG. 6 is a time chart showing a modulation pattern of laser beam power used for recording the amorphous mark according to embodiment 1.

FIG. 7A is a sectional view showing a sample structure in fabrication using a laser beam according to embodiment 2 of the invention.

FIG. 7B is a sectional view for explaining crystallization of a recording film in the fabrication.

FIG. 7C is a sectional view showing a sample formed with an amorphous pattern in the fabrication.

FIG. 7D is a top view of the pattern of FIG. 7C.

FIG. 7E is a top view of a sample formed with a pattern vertical to the FIG. 7D pattern.

FIG. 7F a sectional view of a sample obtained by etching a protective film and a crystalline portion of the recording film of the FIG. 7E sample.

FIG. 7G is a sectional view showing a sample obtained by sputtering Cr on the FIG. F sample.

FIG. 7H is a sectional view of a sample obtained by removing Cr on the recording film by dissolving the recording film.

FIG. 8A is a sectional view showing a sample structure in fabrication using an electron beam according to embodiment 3.

FIG. 8B is a sectional view for explaining partial crystallization of a recording film in the fabrication.

FIG. 8C is a sectional view showing a sample obtained by forming a pattern in the FIG. 8B recording film.

FIG. 8D is a top view of the sample of FIG. 8C.

FIG. 8E is a top view of a pattern formed vertically to the pattern depicted in FIG. 8D.

FIG. 9A is a sectional view showing a sample structure useful to explain a method for pattern correction according to embodiment 4 of the invention.

FIG. 9B is a sectional view for explaining crystallization in a recording film.

FIG. 9C is a sectional view for explaining exposure based on a laser beam and carried out by using a photo mask.

FIG. 9D is a sectional view of a sample formed with an amorphous pattern.

FIG. 9E is a top view of the FIG. 9D sample.

FIG. 9F is a sectional view for explaining partial crystallization of the amorphous pattern under partial irradiation of a laser beam.

FIG. 9G is a top view of the FIG. 9F pattern.

FIG. 10A is a sectional view showing a sample structure useful to explain fabrication using a semiconductor device according to embodiment 5 of the invention.

FIG. 10B is a top view of the sample.

FIG. 10C is a top view useful to explain formatting an amorphous pattern by applying voltages to electrodes 1 and 2.

FIG. 10D is a top view for useful to explain forming an amorphous pattern by applying voltages to electrodes 3 and 4.

FIG. 10E is a top view for explaining pattern correction by crystallizing part of the amorphous pattern through the use of a STM.

FIG. 11A is a sectional view showing a medium structure useful to explain observation of a recording mark of phase-change optical disk according to embodiment 6 of the invention.

FIG. 11B is a sectional view showing a sample after peel off of a polycarbonate sheet.

FIG. 11C is a sectional view showing a sample after crystallization and peel off of lower protective layer and recording film.

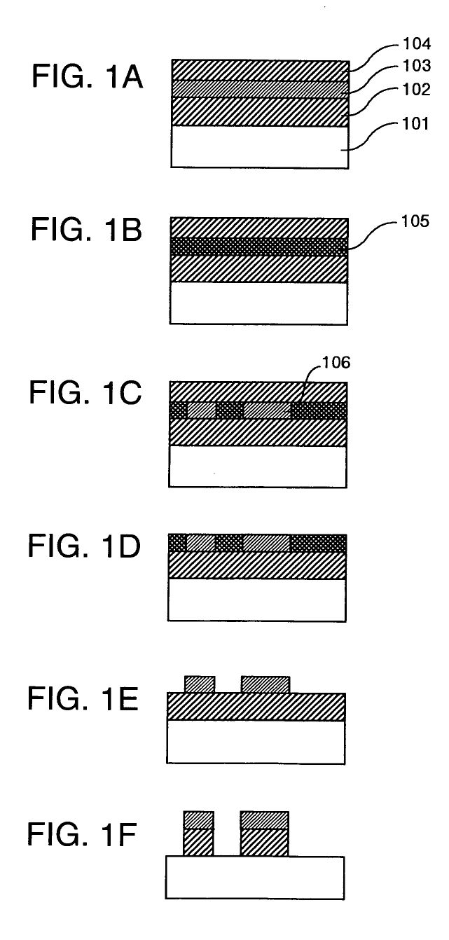

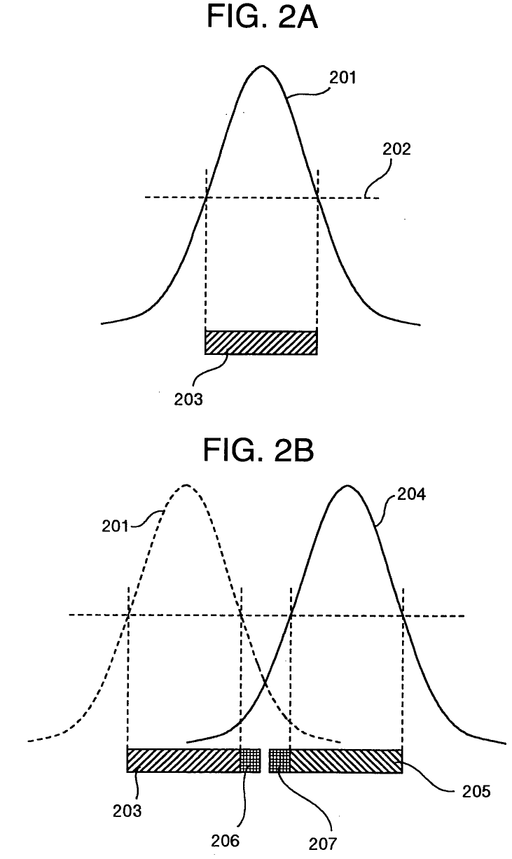

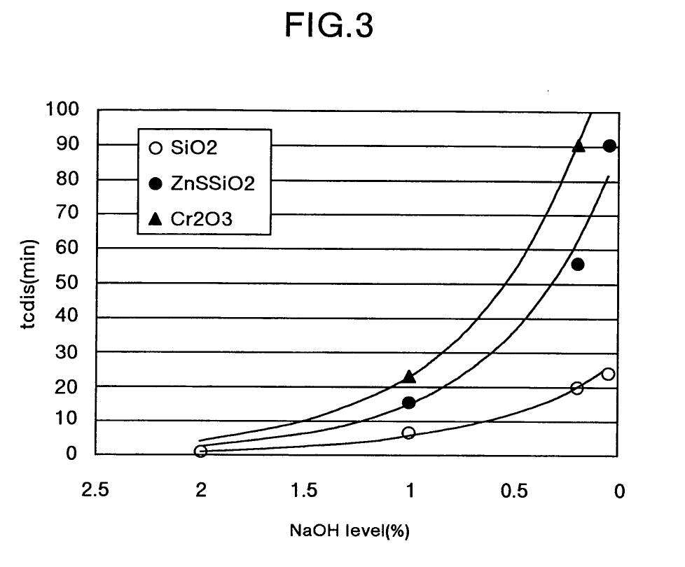

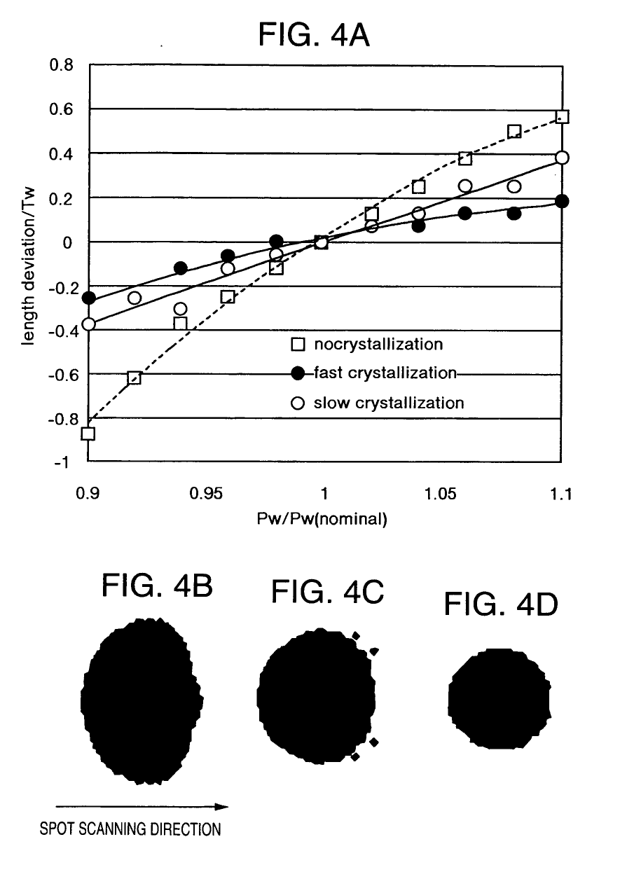

### DESCRIPTION OF THE EMBODIMENTS

The invention will now be described in greater detail by way of example with reference to the accompanying drawings.

### Embodiment 1

A ROM substrate of an optical disk was fabricated using the method set forth so far.

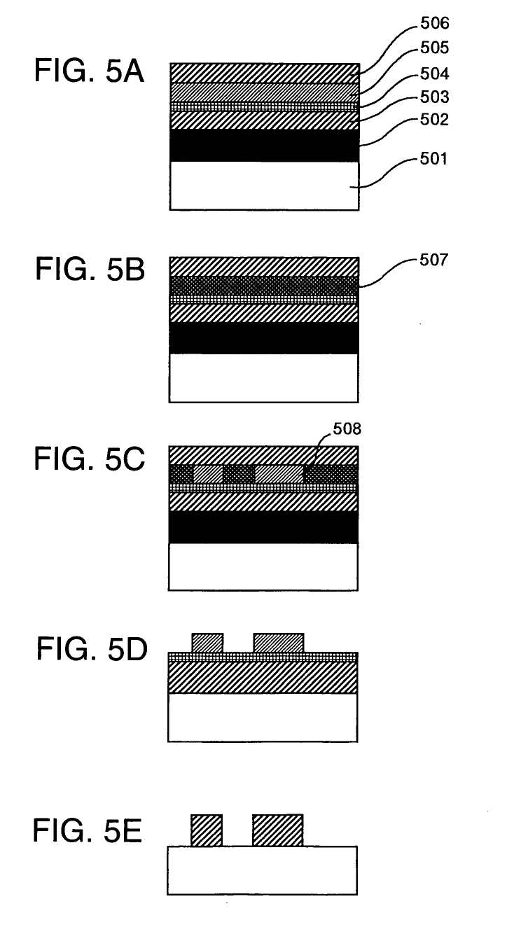

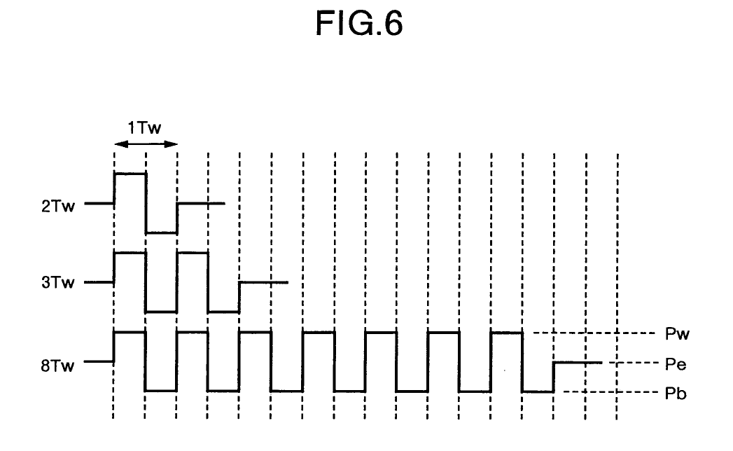

A medium having a structure shown in FIG. 5A was fabricated and on trail, an amorphous mark was recorded by irradiating a laser beam on the medium. All of films stacked on a glass substrate 501 were formed through sputtering process. Protective films were of SiO₂ and with a view to improving adhesiveness between lower SiO₂ protective film 503 and recording film 505, a ZnS.SiO₂ film 504 was interposed. A Ag layer 502 is adapted to diffuse heat generated in the recording film under the irradiation of the laser beam. This medium was heated at 300° C. for 3 minutes in a baking oven to crystallize the recording film 505 as shown at 507 in FIG. 5B. Under this condition, a laser beam having a wavelength of 400 nm was irradiated on the medium from upper part in the drawing through an objective lens of an numerical aperture of 0.9 so as to be focused on the recording film of the medium, so that the recording film was molten locally and an amorphous mark was recorded as shown at 508 in FIG. 5C. A 1-7 modulation code was used in which window width Tw is 74.5 nm, the shortest mark is 2 Tw and the longest mark is 8 Tw. The laser beam for recording was modulated in power as shown in FIG. 6 and the number of pulses was changed in accordance with a mark length to be recorded. Recording power levels Pw, Pe and Pb were 7.0 mW, 3.5 mW and 0.3 nW, respectively. Under this condition, the crystallized recording film was molten locally to record the amorphous mark pattern 508.

Subsequently, the SiO₂ layer 506 was etched through RIE process. As a gas for RIE, CHF₃ was used and etching power was 100 W. Since the etching rate for SiO₂ under this condition is about 0.16 nm/sec., the SiO₂ layer 506 can be etched completely by applying the RIE process to the FIG. 5C structure for about 312 seconds and the recording film can be exposed externally.

After the etching as above, the medium was placed on a spin coater and while rotating the medium, a NaOH solution of 0.02% concentration was dropped onto the vicinity of the center of the medium, thus causing the solution to flow on the medium surface toward the outer edge of the medium. Through this, only a crystalline portion of the recording film was dissolved to leave only the amorphous portion behind, thereby providing a structure as shown in FIG. 5D. In this structure, amorphous was hardly dissolved and a depth of unevenness in FIG. 5D measured with the AFM was about 20 nm.

In this embodiment, for the purpose of producing a ROM pit having a depth of 60 nm, the medium shown in FIG. 5D was etched through RIE process. A gas used for RIE was CHF₃, power was set to 100 W and etching time was set to 484 seconds. Etching rates for the amorphous of recording film and the (ZnS)₈₀(SiO₂)₂₀ film were 0.053 nm/s and 0.047 nm/s, respectively, and therefore, through the 484-seconds RIE process, a portion at which the recording film remained was etched by about 25 nm and a portion removed of the recording film was etched by about 65 nm. The remaining portion of the recording film was initially 20 nm high and therefore, the depth of unevenness was 60 nm in total.

With the sample shown in FIG. 5E used as an original, a ROM substrate made of polycarbonate was produced. The substrate was deposited with Ag to about 50 nm by sputtering and a jitter was measured with an optical disk evaluator to obtain a value of about 3.8%.

### Embodiment 2

The present technique was used to produce on trial a thin line pattern with a laser beam.

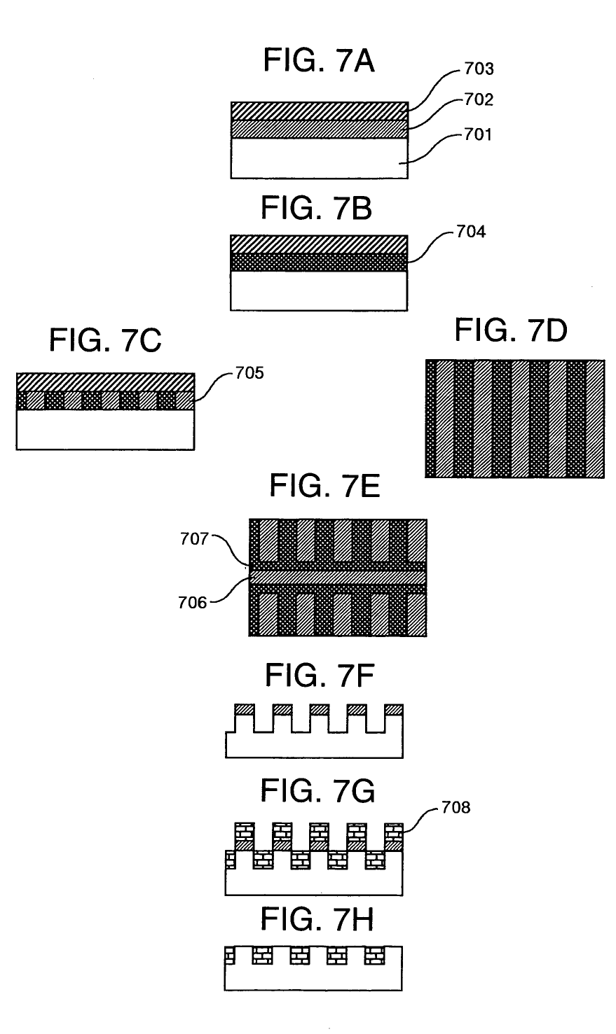

A sample was prepared, having a structure as shown in FIG. 7A. This sample was placed in an oven and annealed at a temperature of 300° C. for 2 minutes to crystallize a recording film as shown at 704 in FIG. 7B. An ArF laser beam having a wavelength of 193 nm was focused on the sample through an objective lens having a numerical aperture of 0.8, so that while dissolving the recording film 704, a spot was scanned to produce an amorphous line and space (L&S) pattern 705 having a width of 50 nm. Laser power was 0.5 mW and the scanning speed was 1 m/s. The sample formed with the pattern is shown in sectional form in FIG. 7C and in top view form in FIG. 7D. Subsequently, an amorphous pattern 706 was recorded in the same manner as the pattern 705 in a direction orthogonal to the parallel pattern 705. At that time, the periphery of the pattern 706 was recrystallized. Accordingly, the pattern 705 was partly crystallized at locations where the pattern 705 intersected the pattern 706, thus forming a recrystallized region 707.

A SiO₂ layer 703 of the resulting sample in FIG. 7E was etched through RIE process and then dipped in pure water for 30 minutes to peel off the crystalline portion. Thereafter, a SiO₂ substrate 701 was etched through RIE process by using the amorphous pattern as a mask to obtain a structure as shown in FIG. 7F. The condition for RIE was the same as that in the first embodiment and the etching time was 316 seconds. Ultimately, the amorphous pattern remained by about 13.5 nm and a pattern having a depth of about 50 nm was formed in the SiO₂ substrate.

A mask for exposure was produced from this pattern. Through sputtering, Cr was deposited by 50 nm on the sample shown in FIG. 7F. The resulting sample was dipped in a NaOH solution of 1% concentration for 30 minutes, so that the amorphous pattern was dissolved to produce a sample as shown in FIG. 7H.

This sample was observed with a scanning tunneling microscope (STM) to indicate that the width of the recrystallized region 707 was about 15 nm.

Subsequently, resist for ArF laser was coated on a Si substrate and the sample of FIG. 7H was brought into intimate contact to the resist. Under this condition, an ArF laser beam was irradiated. This causes the resist to be exposed by a near-field light generating from an inter-Cr pattern. In this case, the near-field light is a light localized at the Cr pattern and has its resolution being independent of (light source wavelength)/NA in contrast to the ordinary propagation beam and determined by the size of the pattern. Therefore, a pattern smaller than (wavelength)/NA can be produced and in this embodiment, a 15 nm pattern of recrystallization region 707 representing an intersection of patterns 705 and 706 could be transcribed to the resist.

### Embodiment 3

In this embodiment, production of a pattern by an electron beam was tried.

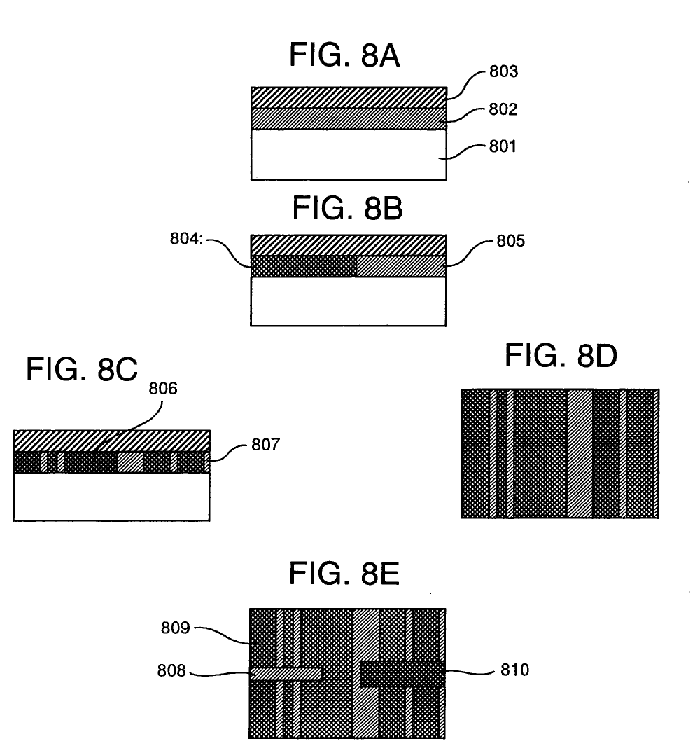

A medium was prepared, having a structure as shown in FIG. 8A. Recording film 802 and Si film 803 were formed on a Si substrate 801 by sputtering. The protective film was made of Si because conductivity was necessary for an electron beam to reach the recording film. In this embodiment, Ge₂Sb₂Te₅ was used for the recording film.

The recording film of this sample was irradiated with the laser beam so as to be crystallized by half as shown in FIG. 8B. As a result, the recording film of the sample was bisected to crystalline region 804 and amorphous region 805.

An electron beam to be focused on the recording film was irradiated from upper part in the drawing in order that a pattern could be produced by Joule's heat generated by a current passing through the recording film. In the crystalline region 804, the recording film was molten with the electron beam subjected to 25 kV accelerating voltage and 1 m/s scanning speed to form an amorphous pattern 806 as shown in FIGS. 8C and 8D. The pattern 806 had a pitch of 30 nm. The amorphous region 805, on the other hand, was raised to such a temperature insufficient to melt the recording film but sufficient for crystallization under the condition that the accelerating voltage was 15 kV and scanning speed was 1 m/s for the irradiating electron beam, thereby forming a crystal pattern 807. The pattern 807 had a pitch of 60 nm.

Patterns 808 and 810 orthogonal to the patterns 806 and 807, respectively, were produced as shown in FIG. 8E. Conditions of the electron beam used to form the patterns 808 and 810 were the same as those for the patterns 806 and 807. The Si film 803 of this sample was removed through RIE process using a Cl₂gas and a resulting structure was dipped in a NaOH solution of 0.02% concentration to dissolve only the crystalline portion. The thus obtained sample was observed with the STM to indicate that the width of pattern 806 was about 15 nm, the width of pattern 807 was about 30 nm and the width of recrystallized region 809 at intersection of the patterns 806 and 808 was about 5 nm.

In this manner, any gap due to recrystallization is not formed at the intersection in the crystallization recording but a gap is formed in the amorphous recording. Thus, the amorphous recording may be used when the gap is desired to be utilized positively but the crystallization recording may be used when the gap is undesirable.

### Embodiment 4

After the amorphous pattern was produced, correction of the pattern was tried.

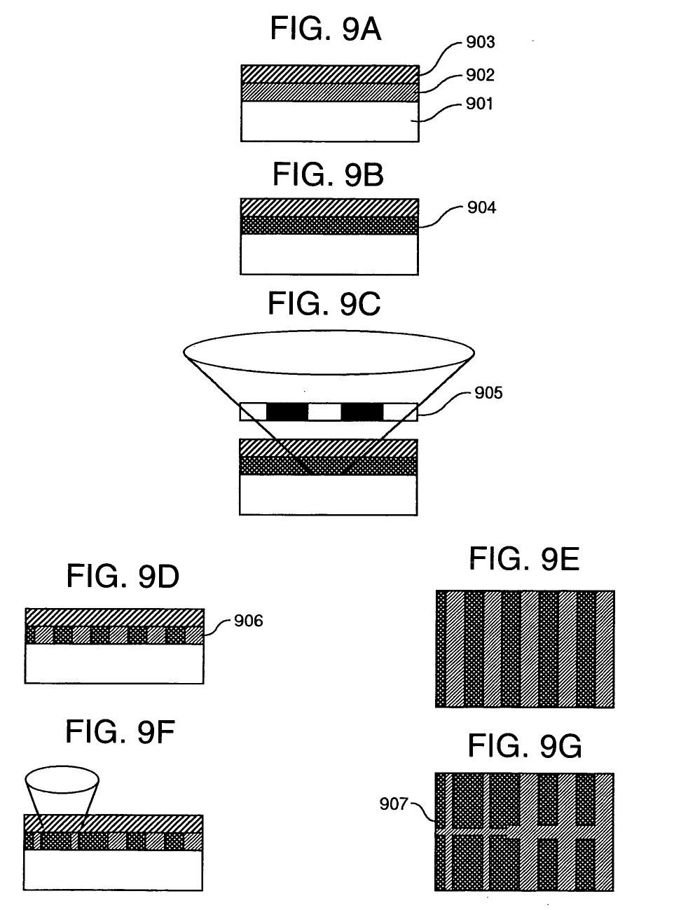

A sample having a structure shown in FIG. 9A was prepared. In this embodiment, Ag₅In₅Sb₇₀Te₂₀ was used for a recording film. This sample was placed in a baking oven and annealed at 250° C. for 3 minutes to crystallize the recording film 902 as shown at 904 in FIG. 9B. A laser pulse was irradiated on the crystallized recording film through a photo mask 905 generally used in exposure for production of semiconductors. The photo mask 905 has a pattern composed of a simple L&S pattern and lines orthogonal to the L&S pattern to intersect it. The laser source of ArF had a wavelength of 193 nm, an objective lens had a NA of 0.8, pulse power was 1 mW and pulse duration was 10 ns. As a result, the recording film was molten at a portion where the laser beam was irradiated to form an amorphous pattern. The above process was repeated by moving the sample by means of a stepper to form an amorphous pattern 906 over the entire sample surface. The thus formed sample is sectioned as shown in FIG. 9D and is viewed from above as shown in FIG. 9E. Since in the second and third embodiments the pattern in longitudinal direction in the drawing was first produced and then the pattern vertical thereto was produced, gaps were formed at intersections owing to recrystallization. In the present embodiment, however, there are solid cross-links because the all the patterns are formed simultaneously using pattern projection using a photo mask.

This sample was partly irradiated with a laser beam as shown in FIG. 9F. The irradiated laser beam having a wavelength of 193 nm was focused on the recording film by means of an objective lens of NA of 0.8 and a spot was scanned by DC power of 0.2 mW at a speed of 1 m/s. As a result, the amorphous was partly crystallized at a portion irradiated with the laser beam. Normally, the process of crystallization is bisected to crystal nucleus generation and crystal growth. That is, a crystal nucleus is first generated and then crystal grows from the nucleus. The rate of crystal nucleus generation and the rate of crystal growth depend on the kind of materials. In the case of the AgInSbTe recording film used in the present embodiment, the crystal nucleus generation is very slow and the crystal growth rate is fast. Accordingly, the temperature rises locally under the irradiation of the laser beam shown in FIG. 9F and when a crystallization temperature range is reached, the crystal growth starts from the periphery of the amorphous pattern and the width of the amorphous pattern is narrowed. Since the crystal nucleus generation hardly takes place, crystallization internal of the amorphous pattern hardly occurs.

The crystalline portion of this sample was etched under the same condition as that in embodiment 2 to form an uneven pattern. The sample was observed with the AFM to indicate that the pattern at a portion not irradiated with the laser beam in FIG. 9F had a width of 100 nm and a pattern 907 constricted in width by the laser beam irradiation had a width of about 50 nm.

### Embodiment 5

By using a semiconductor device, production of a pattern was tested.

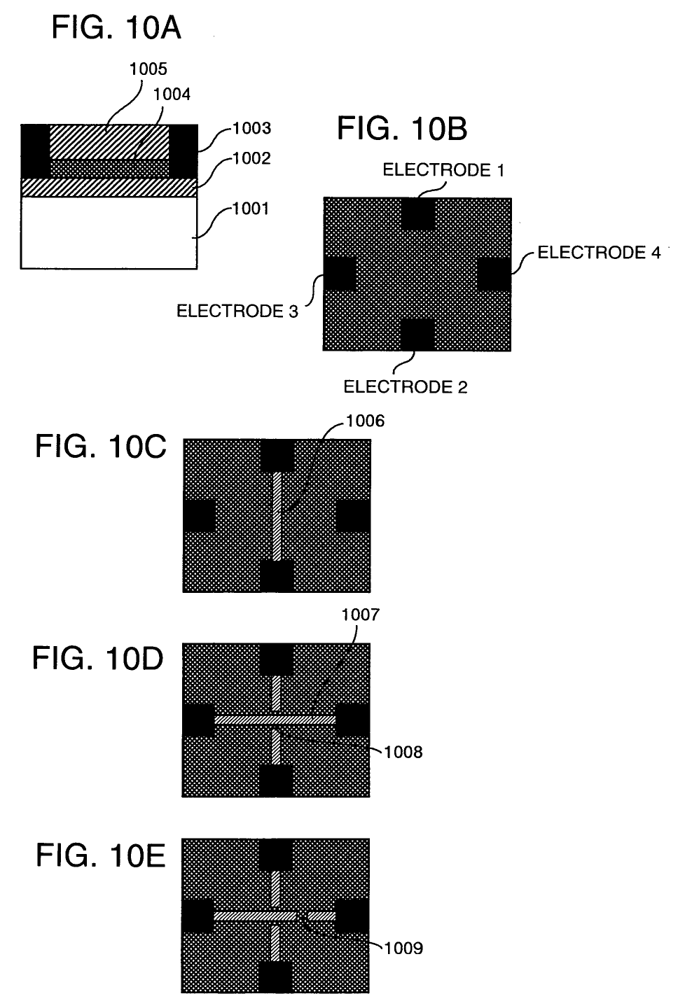

A sample having a structure as shown in FIGS. 10A and 10B was prepared by using the ordinary lithography technique in the field of semiconductors. The sample has a Si substrate 1001 and oxidation layer 1002 and Al electrode 1003 overlying the surface of the substrate and this structure is formed with Ge₂Sb₂Te₅ recording film 1004 and SiO₂ film 1005 through sputtering process. The electrode has a cubic structure having one side of about 200 nm length. The sample was annealed at 300° C. for 3 minutes to crystallize the recording film 1004.

An electrode 1 shown in FIG. 10B was applied with a voltage of +1 V and concurrently an electrode 2 was applied with a voltage of −1 V for 10 ns. This caused a current to flow through the recording film 1004 so as to generate Joule's heat, so that the recording film was molten between the electrodes 1 and 2 to form an amorphous pattern 1006 as shown in FIG. 10C. Next, by applying +1 V to an electrode 3 and at the same time, −1 V to an electrode 4 for 10 ns, an amorphous pattern 1007 was formed as shown in FIG. 10D. In this phase, a recrystallized area 1008 was formed at an intersection of the amorphous patterns 1006 and 1007.

Thereafter, the SiO₂ film 1005 of this sample was etched through RIE process. A CHF₃ gas was used for the RIE and the etching was performed at 100 W power for 1063 seconds. Since the etching rate for SiO₂ under this condition is about 0.16 nm/second as has been described in connection with the first embodiment, the 170 nm SiO₂ film 1005 are all etched in 1063 seconds.

The amorphous pattern of the sample under this condition was corrected using the STM. The electrodes in the sample were applied with 0 V voltage and the probe of STM was applied with a voltage of +1 V and scanned on the sample. Then, a tunneling current flowing between the probe and the surface of the sample was observed to obtain an image of the amorphous pattern. Since amorphous differs from crystal in electrical conductivity, the amorphous pattern image can be obtained by detecting the tunneling current. Subsequently, the probe was guided to a portion to be corrected of the amorphous pattern in the image and +5 V voltage was applied to the probe for 30 ns at that location. As a result, Joule's heat was generated by the flow of a tunneling current to crystallize the amorphous portion locally and the amorphous pattern was corrected as shown in FIG. 10E.

This sample was dipped in a NH₄OH solution of 1% concentration for 30 minutes to dissolve the crystalline portion and a resulting uneven pattern of the sample was observed with the STM. Then, it was confirmed that the unevenness had a height of about 30 nm, the crystal was completely dissolved by etching based on the NH₄OH solution and the amorphous portion was hardly etched to remain. The observed result also indicated that the width of each of the amorphous patterns 1006 and 1007 was about 100 nm, the width of the recrystallized area 1008 was about 10 nm and the width of the recrystatllization corrected portion 1009 was about 6 nm.

In the present embodiment, the pattern was corrected by means of the STM but any other methods for generating heat in the recording film locally can be employed. For example, heat may be generated by a laser or electron beam or by an electric current conducted through the probe of AFM and the thus generated heat may be transferred to the recording film. Also, after the amorphous pattern has been formed, the whole of the sample may be annealed for a short period of time to constrict the formed amorphous pattern as a whole.

### Embodiment 6

Phase-change marks recorded on a phase-change optical disk were observed.

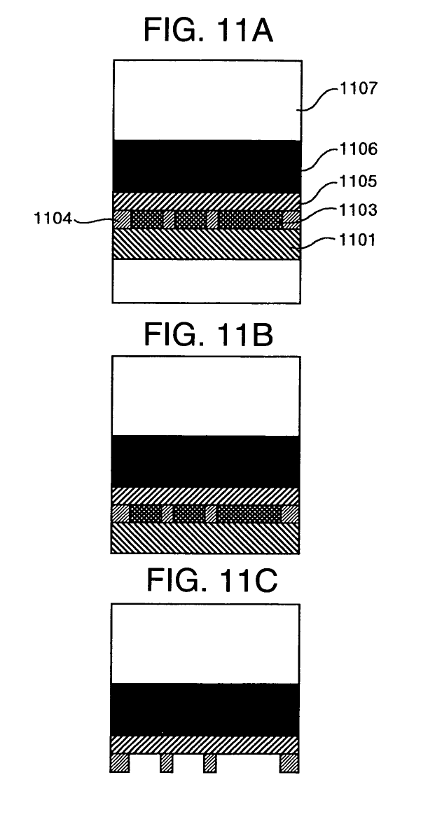

A structure of a phase-change optical disk is shown in FIG. 11A. The disk includes a 0.1-mm thick polycarbonate sheet 1101, a lower protective film 1102, a recording film comprised of a crystalline portion 1103 and an amorphous mark 1104, an upper protective layer 1105, a reflection film 1106 and a 1.1-mm thick polycarbonate substrate 1107. By cutting the disk in the radial direction and peeling off the sheet 1101, all of the aforementioned films, excepting only the sheet 1101, remained on the side of substrate 1107 as shown in FIG. 11B.

The lower protective layer 1102 of the sample was etched through RIE process. A CHF₃ gas was used for the RIE and power was set to 100 W. Whether the lower protective layer was etched completely was confirmed by measuring the reflectiviti of the sample after etching. More specifically, the sample was gradually etched through the RIE process and dependency of the reflectivity of the sample as viewed from lower part in FIG. 11B upon RIE processing time was measured. The reflectivity depends on the thickness of the lower protective layer and therefore, as the RIE proceeds, the reflectivity changes. But when etching of the recording film is started after the lower protective layer has been etched completely, the reflectivity changes abruptly increasingly. The reason for this is that while the protective film is almost transparent, the recording film is optically absorptive and as the thickness of this light absorptive layer changes, the reflectivity changes increasingly.

Through the above method, only the lower protective layer 1102 was etched completely. The resulting sample was dipped in pure water for 90 minutes and the crystalline portion was peeled off to obtain a structure shown in FIG. 11C. When the sample was observed with the SEM to observe the shape of a mark, it was confirmed that the mark shape was substantially identical to the mark shape image obtained by observing the equivalent medium with the TEM. This sample was also observed with the AFM, confirming that an uneven configuration was similar to the mark shape obtained through the SEM observation.

The prosecution of the above fabrication to obtain an SEM image after medium recording could be completed in about one day.

The present invention can also be applicable to an observation method in addition to the fine fabrication method.

It should be further understood by those skilled in the art that although the foregoing description has been made on embodiments of the invention, the invention is not limited thereto and various changes and modifications may be made without departing from the spirit of the invention and the scope of the appended claims.

1. A method of fabricating a device wherein an uneven configuration is formed in the device having a crystalline region and an amorphous region by selectively removing any one of said crystalline region and said amorphous region.

2. A device fabrication method according to claim 1, wherein said device essentially consists of at least one kind of substances Ge, In, Sb and Te.

3. A device fabrication method according to claim 1, wherein said uneven configuration is formed using pure water or an alkaline solution.

4. A device fabrication method according to claim 1, wherein said crystalline region and said amorphous region are formed by energy irradiation and said amorphous region is produced through melting process.

5. A device fabrication method according to claim 1, wherein said crystalline region and said amorphous region are formed by energy irradiation and said energy is of at least any one of electron beam and electric current.

6. A device fabrication method according to claim 1, wherein said device has a substrate, a lower protective layer and a phase-change film, and said crystalline region and said amorphous region are formed in said phase-change film.

7. An observation method wherein an uneven configuration is formed in a device having a crystalline region and an amorphous region by selectively removing any one of said crystalline region and said amorphous region, and the device having said uneven configuration is observed.

8. An observation method according to claim 7, wherein said uneven shape is formed using pure water or an alkaline solution.

9. A method for fabrication of a device, comprising the steps of:
irradiating energy to the device having a substrate and a phase-change film to melt a predetermined region of said phase-change film so that an amorphous region and a recrystallized region may be formed in said molten region; and
forming an uneven configuration by selectively removing any one of said amorphous region and said recrystallized region.

10. A device fabrication method according to claim 9, wherein said recrystallized region is formed peripherally of said amorphous region and said uneven configuration is formed by selectively removing said recrystallized region.
